(19) United States
(12) Patent Application Publication
(10) Pub. No.: US 2024/0145566 A1
(43) Pub. Date: May 2, 2024

(54) Structure and Method for Gate-All-Around Devices with Dielectric Interposer

(71) Applicant: Taiwan Semiconductor Manufacturing Company, Ltd., Hsin-Chu (TW)

(72) Inventors: Ka-Hing Fung, Hsinchu (TW); Wei-Yang Lee, Taipei City (TW); Huiling Shang, Hsinchu (TW)

(21) Appl. No.: 18/159,814

(22) Filed: Jan. 26, 2023

Related U.S. Application Data
(60) Provisional application No. 63/382,038, filed on Nov. 2, 2022.

(51) Int. Cl. H01L 29/423; H01L 21/8234; H01L 29/08; H01L 29/66; H01L 29/786

(52) U.S. Cl. CPC H01L 29/42392; H01L 21/823412; H01L 21/823418; H01L 21/823468; H01L 29/0847; H01L 29/66545; H01L 29/6656; H01L 29/78696

(57) ABSTRACT

A method includes forming a structure having a dummy gate stack over a multi-layer stack (ML) disposed on a semiconductor substrate, the ML including alternating channel layers and non-channel layers; recessing the ML in source/drain (S/D) regions; removing the non-channel layers to form first openings between the channel layers; depositing a dielectric material in the first openings; recessing the dielectric material to form undercuts; forming inner spacers in the undercuts; forming epitaxial S/D features in the S/D regions; removing the dummy gate stack to form a gate trench; removing the dielectric material from the gate trench to form second openings between the channel layers; and forming a metal gate stack in the gate trench and the second openings.

### PRIORITY DATA

This application claims priority to U.S. Provisional Patent Application Ser. No. 63/382,038 filed on Nov. 2, 2022, the entire disclosure of which is hereby incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Recently, multigate devices have been introduced to improve gate control. Multigate devices have been observed to increase gate-channel coupling, reduce OFF-state current, and/or reduce short-channel effects (SCEs). One such multigate device is the gate-all around (GAA) device, which includes a gate structure that can extend, partially or fully, around a channel region to provide access to the channel region on at least two sides. GAA devices enable aggressive scaling down of IC technologies, maintaining gate control and mitigating SCEs, while seamlessly integrating with conventional IC manufacturing processes. As GAA devices continue to scale, challenges have arisen. For example, the existing structures and fabrication technologies have various issues, which includes abnormal doping diffusion, increased built-in stress, undesired capacitance, device degradation, scaling limit by overlap requirement, and other structure-related issues and/or process-related issues especially as device size is scaled down. Although existing structure and fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B are a flowchart of a method for fabricating a semiconductor structure according to various aspects of the present disclosure.

FIG. 2 is a top view of a semiconductor structure according to some embodiments of the present disclosure.

FIGS. 3, 4A-9A, 10, and 11A-12A are cross sectional views of a semiconductor structure along the line A-A′ in FIG. 2, at various fabrication stages, according to some embodiments of the present disclosure.

FIGS. 4B-9B and 11B-12B are enlarged views of a portion of the semiconductor structure in FIGS. 4A-9A and 11A-12A, respectively, according to some embodiments of the present disclosure.

FIG. 11C is a cross sectional view of the semiconductor structure in FIG. 11A and along the line B-B′ as in FIG. 2, according to some embodiments of the present disclosure.

### DETAILED DESCRIPTION

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

Multi-gate devices (e.g. gate-all-around (GAA) devices) have been introduced in an effort to improve gate control by increasing gate-channel coupling, reduce OFF-state current, and reduce short-channel effects (SCEs). GAA devices can be aggressively scaled down while maintaining gate control and mitigating SCEs. However, conventional methods for GAA devices may experience challenges, including abnormal doping diffusion, increased built-in stress, undesired intermix layer between semiconductor layers, device degradation, and increased capacitance between adjacent conductive regions, such as between a source/drain region and SiGe residue. These drawbacks are exacerbated as device size is scaled down.

The present disclosure is generally related to ICs and semiconductor devices and methods of forming the same. More particularly, the present disclosure is related to GAA devices. A GAA device includes any device that has its gate structure, or portions thereof, formed around all-sides of a channel region (e.g. surrounding a portion of a channel region). In some instances, a GAA device may also be referred to as a quad-gate device where the channel region has four sides and the gate structure is formed on all four sides. The channel region of a GAA device may include one or more semiconductor layers, each of which may be in one of many different shapes, such as wire (or nanowire), sheet (or nanosheet), bar (or nano-bar), and/or other suitable shapes. In embodiments, the channel region of a GAA device may have multiple horizontal semiconductor layers (such as nanowires, nanosheets, or nano-bars) (hereinafter collectively referred to as “nanochannels”) vertically spaced, making the GAA device a stacked horizontal GAA device. The GAA devices presented herein may be a complementary metal-oxide-semiconductor (CMOS) GAA device, a p-type metal-oxide-semiconductor (pMOS) GAA device, or an n-type metal-oxide-semiconductor (nMOS) GAA device. Further, the GAA devices may have one or more channel regions associated with a single, contiguous gate structure, or multiple gate structures. One of ordinary skill may recognize other examples of semiconductor devices that may benefit from aspects of the present disclosure. For example, other types of metal-oxide semiconductor field effect transistors (MOSFETs), such as planar MOSFETs, FinFETs, other multi-gate FETs may benefit from the present disclosure. The GAA devices and methods of manufacture that are proposed in the present disclosure exhibit desirable properties, examples being: reduced doping diffusion, reduced built-in stress, reduced device degradation, improved silicon performance, higher current drive, reduced short-channel effects (SCEs), and decreased capacitance between adjacent conductive regions, such as between a source/drain region and adjacent SiGe residue.

In the illustrated embodiments, an IC device includes a semiconductor structure (e.g., a GAA device) 200. The semiconductor structure 200 may be fabricated during processing of the IC, or a portion thereof, that may include static random access memory (SRAM) and/or logic circuits, passive components such as resistors, capacitors, and inductors, and active components such as p-type field effect transistors (pFETs), n-type FETs (nFETs), FinFETs, MOSFETs, CMOS, bipolar transistors, high voltage transistors, high frequency transistors, other memory cells, and combinations thereof.

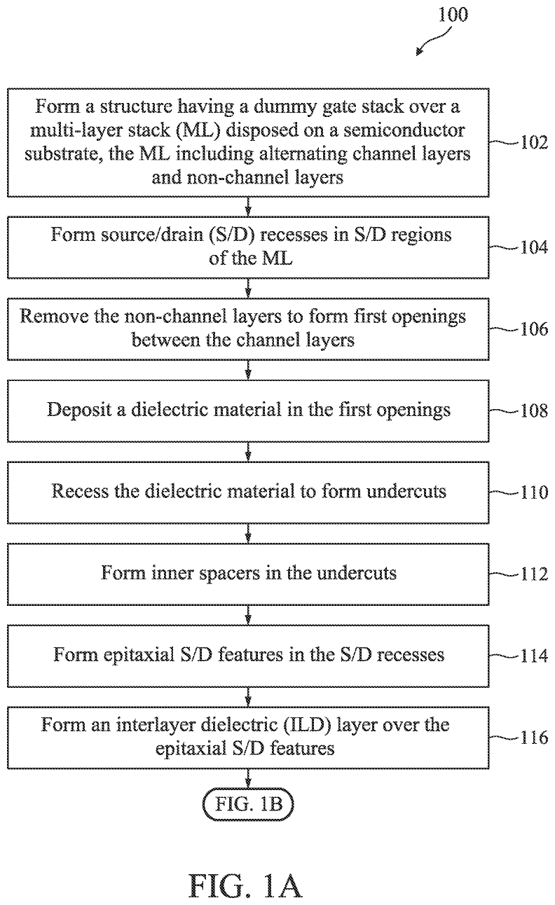

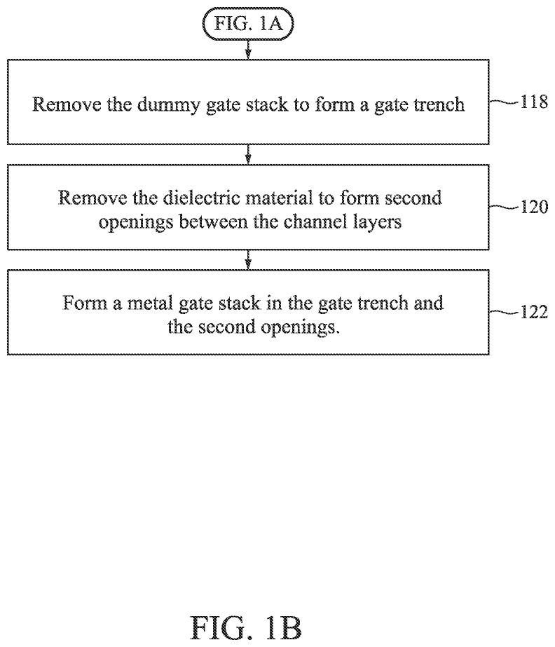

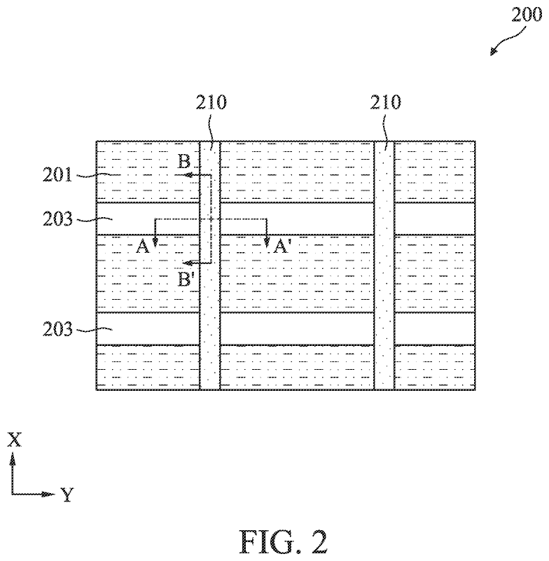

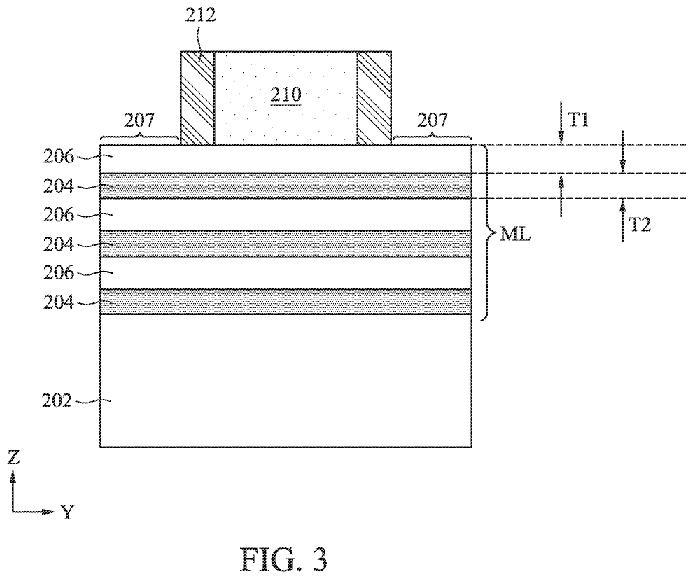

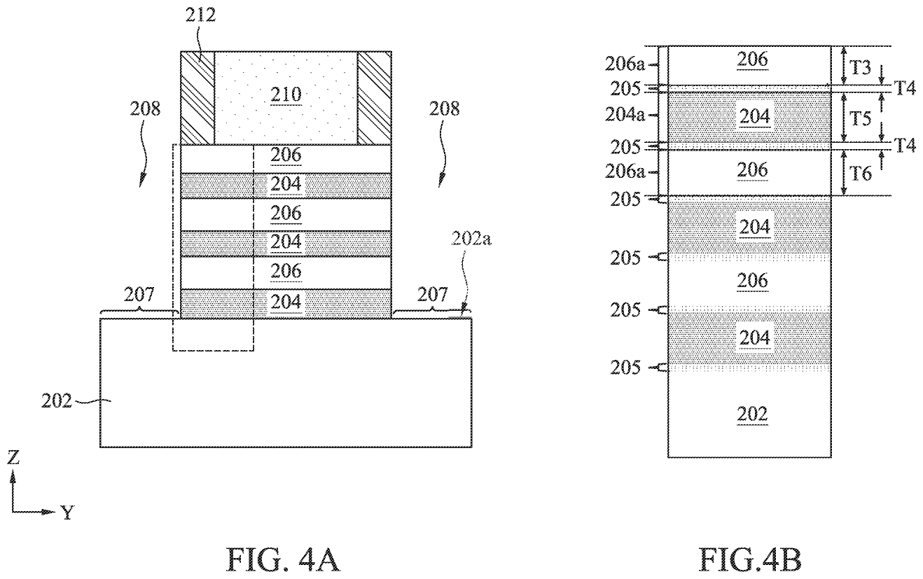

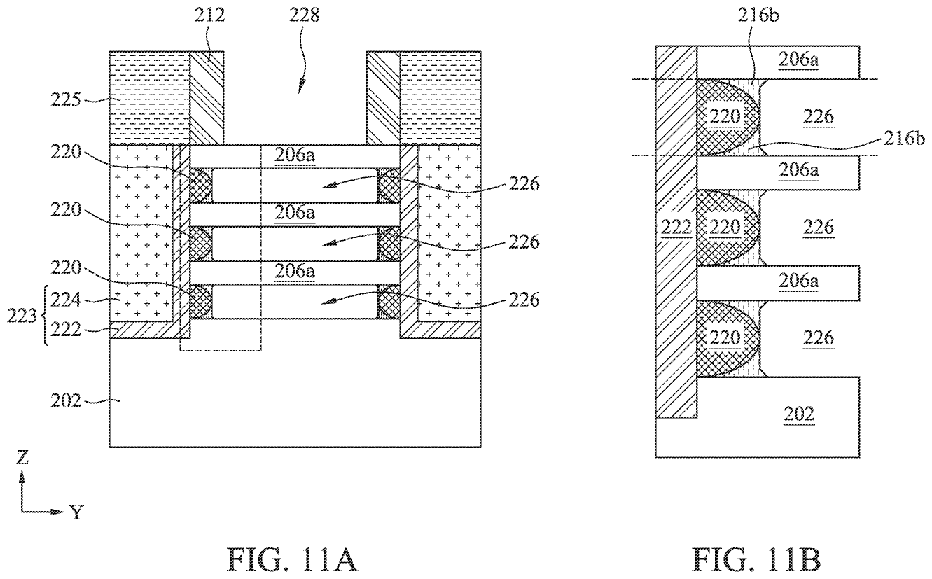

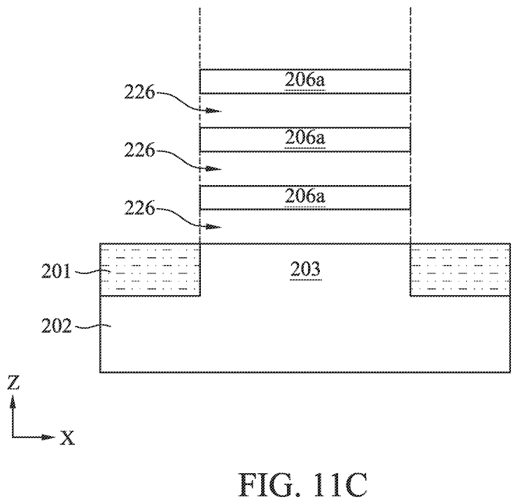

FIGS. 1A-1B are flow charts of an example method 100 for fabricating an embodiment of a semiconductor structure according to some embodiments of the present disclosure. FIG. 2 is a top view of a semiconductor structure according to some embodiments of the present disclosure. FIGS. 3, 4A-9A, 10, and 11A-12A are cross sectional views of a semiconductor structure along the line A-A′ in FIG. 2, at various fabrication stages, according to some embodiments of the present disclosure. FIGS. 4B-9B and 11B-12B are enlarged views of a portion of the semiconductor structure in FIGS. 4A-9A and 11A-12A, respectively, according to some embodiments of the present disclosure. FIG. 11C is a cross sectional view of the semiconductor structure in FIG. 11A and along the line B-B′ in FIG. 2, according to some embodiments of the present disclosure.

Referring to block 102 of FIG. 1A and FIGS. 2 and 3, the method 100 comprises forming a semiconductor structure 200. The semiconductor structure 200 includes one or more fins 203 protruding from a semiconductor substrate 202 and separated by isolation features 201 and one or more dummy gate stacks 210 disposed over the fins 203.

In some embodiments, the semiconductor substrate 202 includes a semiconductor material, such as bulk silicon (Si). Alternatively or additionally, another elementary semiconductor, such as germanium (Ge) in a crystalline structure, may also be included in the semiconductor substrate 202. The semiconductor substrate 202 may also include a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb), or combinations thereof. The semiconductor substrate 202 may also include a semiconductor-on-insulator substrate, such as Si-on-insulator (SOI), SiGe-on-insulator (SGOI), Ge-on-insulator (GOI) substrates.

Portions of the semiconductor substrate 202 may be doped and referred to as doped portions. The doped portions may be doped with p-type dopants, such as boron (B) or boron fluoride (BF₃), or doped with n-type dopants, such as phosphorus (P) or arsenic (As). The doped portions may also be doped with combinations of p-type and n-type dopants (e.g. to form a p-type well and an adjacent n-type well). The doped portions may be formed directly on the semiconductor substrate 202, in a p-well structure, in an n-well structure, in a dual-well structure, or using a raised structure.

In some embodiments, semiconductor layers 204 and 206 (collectively referred to as a “multi-layer stack” or “ML”) are formed over the semiconductor substrate 202 in an interleaving or alternating fashion, extending vertically (e.g. along the Z-direction) from the semiconductor substrate 202. For example, a semiconductor layer 204 is disposed over the semiconductor substrate 202, a semiconductor layer 206 is disposed over the semiconductor layer 204, another semiconductor layer 204 is disposed over the semiconductor layer 206, so on and so forth. In the depicted embodiments, there are three layers of semiconductor layers 206 and three layers of semiconductor layers 204 alternating between each other. However, there may be any appropriate number of layers in the ML. For example, there may be 2 to 10 layers of semiconductor layers 206, alternating with 2 to 10 layers of semiconductor layers 204 in the ML. The material compositions of the semiconductor layers 206 and the semiconductor layers 204 are configured such that they have an etching selectivity in a subsequent etching process. For example, in some embodiments, the semiconductor layers 204 contain silicon germanium (SiGe), while the semiconductor layers 206 contain silicon (Si). In some other embodiments, the semiconductor layers 206 contain SiGe, while the semiconductor layers 204 contain Si. In the depicted embodiment, each of the semiconductor layers 206 has a substantially same thickness (e.g., less than 5% difference between two semiconductor layers 206), depicted in FIG. 3 as thickness T1, while each of the semiconductor layers 204 has a substantially same thickness (e.g., less than 5% difference between two semiconductor layers 204), depicted in FIG. 3 as thickness T2. T1 and T2 are about 2 nm to about 12 nm.

The stack of semiconductor layers 204 and 206 are then patterned into a plurality of fin structures, for example, into the fins 203 as in FIG. 2. Each of the fins 203 includes a stack of the semiconductor layers 204 and 206 disposed in an alternating manner with respect to one another. The fins 203 each extends lengthwise (e.g. longitudinally) in a first direction (e.g. in the Y-direction) and are separated from each other (e.g. laterally) in a second direction (e.g. in the X-direction), as shown in FIG. 2. It is understood that the X-direction and the Y-direction are horizontal directions that are perpendicular to each other, and that the Z-direction is a vertical direction that is orthogonal (or normal) to a plane defined by the X-direction and the Y-direction. The semiconductor substrate 202 may have its top surface aligned in parallel to the X-Y plane.

The fins 203 may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins. The patterning may utilize multiple etching processes which may include a dry etching and/or wet etching. The regions in which the fins are formed will be used to form active devices through subsequent processing and are thus referred to as active regions. For example, each of the fins 203 is formed in an active region. Both of the fins 203 in FIG. 2 protrude out of the semiconductor substrate 202 (e.g., the doped portions).

The semiconductor structure 200 includes isolation features 201, which may be shallow trench isolation (STI) features. The isolation features 201 are formed on the semiconductor substrate 202 and are surrounding the active regions. In some examples, formation of the isolation features 201 includes etching trenches into the semiconductor substrate 202 between the active regions and filling the trenches with one or more dielectric materials such as silicon oxide, silicon nitride, silicon oxynitride, other suitable materials, or combinations thereof. Any appropriate methods, such as a chemical vapor deposition (CVD) process, an atomic layer deposition (ALD) process, a physical vapor deposition (PVD) process, a plasma-enhanced CVD (PECVD) process, a plasma-enhanced ALD (PEALD) process, and/or combinations thereof may be used for depositing the isolation features 201. The isolation features 201 may have a multi-layer structure such as a thermal oxide liner layer over the semiconductor substrate 202 and a filling layer (e.g., silicon nitride or silicon oxide) over the thermal oxide liner layer. Alternatively, the isolation features 201 may be formed using any other isolation formation techniques. Although not depicted, in some embodiments, the fins 203 are located above a top surface of the isolation features 201 (e.g. protrude out of the isolation features 201) and are also located above a top surface of the semiconductor substrate 202.

Referring to FIGS. 2 and 3, the dummy gate stacks 210 are formed over a portion of each of the fins 203, and over the isolation features 201, in between the fins 203. The dummy gate stacks 210 may be configured to extend lengthwise (e.g. longitudinally) in parallel to each other, for example, each along the X-direction, as shown in FIG. 2. In some embodiments, each dummy gate stack 210 wraps around the top surface and side surfaces of each of the fins 203. The dummy gate stack 210 may include polysilicon. In some embodiments, the dummy gate stack 210 also includes one or more mask layers, which are used to pattern the dummy gate electrode layers. The dummy gate stack 210 may undergo a gate replacement process through subsequent processing to form metal gates, such as a high-k metal gate, as discussed in greater detail below. The dummy gate stack 210 may also undergo a second gate replacement process to form a dielectric based gate that electrically isolates the semiconductor structure 200 from neighboring devices. The dummy gate stack 210 may be formed by a procedure including deposition, lithography patterning, and etching processes. The deposition processes may include CVD, ALD, PVD, other suitable methods, and/or combinations thereof.

Referring to FIG. 3, gate spacers 212 are formed on sidewalls of the dummy gate stack 210. The gate spacers 212 include one or more dielectric materials and may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The gate spacers 212 may include a single layer or a multi-layer structure. In some embodiments, each of the gate spacers 212 may have a thickness (e.g. measured in the Y-direction) in a range from about 3 nm to about 10 nm. A thickness within the stated range of values may be needed for device performance, especially for advanced technology nodes. In some embodiments, the gate spacers 212 may be formed by depositing a spacer layer (containing the dielectric material) over the dummy gate stack 210, followed by an anisotropic etching process to remove portions of the spacer layer from the top surfaces of the dummy gate stack 210. After the etching process, portions of the spacer layer on the sidewall surfaces of the dummy gate stack 210 substantially remain and become the gate spacers 212. In some embodiments, the anisotropic etching process is a dry (e.g. plasma) etching process. Additionally or alternatively, the formation of the gate spacers 212 may also involve chemical oxidation, thermal oxidation, ALD, CVD, and/or other suitable methods. In the active regions, the gate spacers 212 are formed over the top layer of the semiconductor layers 204 and 206. Accordingly, the gate spacers 212 may also be interchangeably referred to as top spacers 212. In some examples, one or more material layers (not shown) may also be formed between the dummy gate stack 210 and the corresponding gate spacers 212. The one or more material layers may include an interfacial layer and/or a high-k dielectric layer, as examples.

Referring to block 104 in FIG. 1 and FIG. 4A, exposed portions of the fins 203 (i.e., source/drain regions 207 of the fins 203 that are not covered by the dummy gate stack 210) are at least partially removed to form source/drain recesses (trenches) 208. Source/drain region(s) may refer to a source or a drain, individually or collectively, depending upon the context. In the depicted embodiment, an etching process completely removes the ML in the source/drain regions 207 of the fins 203, thereby exposing substrate portions of the fins 203 in the source/drain regions 207. The source/drain recesses 208 thus have sidewalls defined by remaining portions of the ML, which are disposed under the dummy gate stack 210, and bottoms defined by the semiconductor substrate 202. A top surface 202a of the semiconductor substrate 202 is exposed to the source/drain recesses 208. In some embodiments, the etching process removes some, but not all, of the ML, such that the source/drain recesses 208 have bottoms defined by the semiconductor layer 204 or the semiconductor layer 206 in the source/drain regions 207. In some embodiments, the etching process further removes some, but not all, of the substrate portions of the fins 203, such that the source/drain recesses 208 extend below a topmost surface of the semiconductor substrate 202. In other words, the top surface 202a is below a topmost surface of the semiconductor substrate 202. The etching process can include a dry etching process, a wet etching process, other suitable etching process, or combinations thereof. In some embodiments, the etching process is a multi-step etch process. For example, the etching process may alternate etchants to separately and alternately remove the semiconductor layers 204 and the semiconductor layers 206. In some embodiments, parameters of the etching process are configured to selectively etch the ML with minimal (to no) etching of the dummy gate stack 210 and the gate spacers 212 and/or the isolation features 201. In some embodiments, a lithography process, such as those described herein, is performed to form a patterned mask layer that covers the dummy gate stack 210 and the gate spacers 212 and/or the isolation features 201, and the etching process uses the patterned mask layer as an etch mask.

FIG. 4B is an enlarged view of a portion (in the dotted rectangle) of the semiconductor structure 200 in FIG. 4A. In some embodiments, the semiconductor structure 200 further includes intermix layers 205 (also referred to as “transmission layers 205”) having a mixture of materials of the semiconductor layers 204 and the semiconductor layers 206. In some embodiments, the intermix layers 205 are formed from epitaxial growing of the semiconductor layers 204 and 206. The ML can include the intermix layers 205 and core layers 206a and 204a. The core layers 206a and 204a include relatively high concentrations (e.g., greater than 90%) of materials of the semiconductor layers 204 and 206 (e.g., Si or SiGe), respectively. Each of the semiconductor layers 206 can include a core layer 206a and at least a portion of an intermix layer 205. Each of the semiconductor layers 204 can include a core layer 204a and at least a portion of an intermix layer 205. In some embodiments, the core layer 206a is adjacent to and above the intermix layer 205, in such intermix layer 205, a concentration of the material of the core layer 206a (e.g., Si) gradually decreases from about 90% to about 10% from top to bottom along the Z-direction, while a concentration of the material of the core layer 204a (e.g., SiGe) gradually increases from about 10% to about 90% from top to bottom along the Z-direction. In such embodiments, an atomic percentage of Ge in the intermix layer 205 gradually increases from about 0.005% to about 20% from top to bottom along the Z-direction. In some other embodiments, the core layer 204a is adjacent to and above the intermix layer 205, in such intermix layer 205, a concentration of the material of the core layer 206a (e.g., Si) gradually increases from about 10% to about 90% from top to bottom along the Z-direction, while a concentration of the material of the core layer 204a (e.g., SiGe) gradually decreases from about 90% to about 10% from top to bottom along the Z-direction. In such embodiments, an atomic percentage of Ge in intermix layers 205 gradually decreases from about 20% to about 0.005% from top to bottom along the Z-direction. In some embodiments, the bottommost intermix layer 205 has a concentration of the material of the semiconductor substrate 202 (e.g., Si) gradually increases from about 10% to about 90% from top to bottom along the Z-direction, while a concentration of the material of the core layer 204a (e.g., SiGe) gradually decreases from about 90% to about 10% from top to bottom along the Z-direction.

In the depicted embodiment, the core layer 206a interfacing only one layer of the intermix layers 205 has a thickness T3 ranging from about 2 nm to about 12 nm, the core layer 206a interfacing two layers of the intermix layers 205 has a thickness T6 ranging from about 2 nm to about 12 nm, the core layer 204a interfacing two layers of the intermix layers 205 has a thickness T5 ranging from about 2 nm to about 12 nm, and each of the intermix layers 205 has a substantially same thickness (e.g., less than 5% difference) T4 ranging from about 0.1 nm to about 2 nm. T5 can be equal to T6. In some embodiments, T5 is different from T6.

In some embodiments, each of the semiconductor layers 204 and 206 and the intermix layers 205 have uniform profiles on each X-Y plane. For example, on an X-Y plane across one layer of the intermix layers 205, a concentration of the material of the core layer 204a (e.g., SiGe) is substantially the same. Therefore, an interface between the intermix layer 205 and the adjacent core layer 204a or 206a extends along an X-Y plane, and thicknesses of each core layers 206a or 204a are substantially the same at different locations on an X-Y plane. For example, a thickness of a core layer 206a or 204a close to a sidewall of the core layer 206a or 204a is substantially the same (e.g., less than 5% difference) as a thickness of the core layer 206a or 204a at center (the portion directly under dummy gate stack 210). Similarly, thicknesses of each intermix layers 205 are substantially the same at different locations on an X-Y plane. For example, a thickness of a intermix layer 205 close to a sidewall of the intermix layer 205 is substantially the same (e.g., less than 5% difference) as a thickness of the intermix layer 205 at center (the portion directly under dummy gate stack 210).

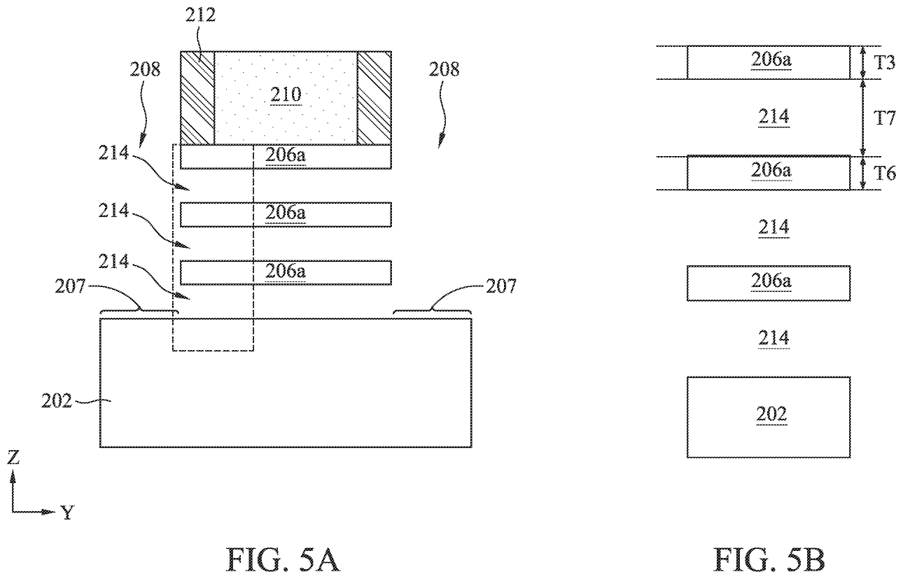

Referring to block 106 in FIG. 1 and FIG. 5A, the semiconductor layers 204 (exposed by the source/drain recesses 208) are selectively removed from the ML, thereby forming suspended semiconductor layers 206 and openings 214 in between the vertically (e.g. in the Z-direction) adjacent semiconductor layers 206 (or the semiconductor substrate 202, where applicable). Particularly, the openings 214 are through openings that are overlapped with the core layers 204a and the intermix layers 205, and are spanning between a pair of the source/drain regions 207. The openings 214 are also referred to as “first openings,” as in block 106 of FIG. 1A. FIG. 5B is an enlarged view of a portion (in the dotted rectangle) of the semiconductor structure 200 in FIG. 5A.

In the depicted embodiment, an etching process selectively etches the core layers 204a and the intermix layers 205 with minimal (to no) etching of the core layers 206a and, in some embodiments, minimal (to no) etching of the gate spacers 212. In embodiments, the core layers 206a remain unetched. In some embodiments, the semiconductor layers 204 are completely removed. In the depicted embodiment, the core layers 204a and the intermix layers 205 are completely removed, thus remaining semiconductor layers 206 only include the core layers 206a. In some other embodiments, the core layers 204a are completely removed, while the intermix layers 205 are partially removed, thus the core layers 206a and the remaining portion of the intermix layers 205 collectively form the remaining semiconductor layers 206. For ease of description, regardless of whether the intermix layers 205 are completely removed, the remaining semiconductor layers 206 hereinafter are referred to as core layers 206a. Various etching parameters can be tuned to achieve selective etching of the core layers 204a and the intermix layers 205, such as etchant composition, etching temperature, etching solution concentration, etching time, etching pressure, source power, Radio-Frequency (RF) bias voltage, RF bias power, etchant flow rate, other suitable etching parameters, or combinations thereof. For example, an etchant is selected for the etching process that etches the material of the core layers 204a (in the depicted embodiment, silicon germanium) at a higher rate than the material of the core layers 206a (in the depicted embodiment, silicon) (i.e., the etchant has a high etch selectivity with respect to the material of the core layers 204a). The intermix layers 205 include certain concentrations of the material of the core layers 204a and thus can be selectively removed with the core layers 204a. The etching process is a dry etching process, a wet etching process, other suitable etching process, or combinations thereof. In some embodiments, a dry etching process (such as an RIE process) utilizes a fluorine-containing gas (for example, SF₆) to selectively etch the core layers 204a and the intermix layers 205. In some embodiments, a ratio of the fluorine-containing gas to an oxygen-containing gas (for example, O₂), an etching temperature, and/or an RF power may be tuned to selectively etch silicon germanium or silicon. In some embodiments, a wet etching process utilizes an etching solution that includes ammonium hydroxide (NH₄OH) and water (H₂O) to selectively etch the core layers 204a and the intermix layers 205. In some embodiments, a chemical vapor phase etching process using hydrochloric acid (HCl) selectively etches the core layers 204a and the intermix layers 205.

In the depicted embodiment, the ML includes three suspended core layers 206a vertically stacked that will provide three channels through which current will flow between respective epitaxial source/drain features during operation of the semiconductor structure 200. The core layers 206a are thus referred to as channel layers 206a hereinafter. The channel layers 206a are separated from each other by one of the openings 214. The channel layers 206a are also separated from the semiconductor substrate 202 by one of the openings 214. A spacing T7 is defined between channel layers 206a along the z-direction. The spacing T7 corresponds with a width of the openings 214 along the Z-direction. In the depicted embodiment, the core layers 204a and the intermix layers 205 are completely removed, thus the spacing T7 is equal to (T5+2*T4), which is a sum of thicknesses of one of the core layer 204a and two intermix layers 205. In some other embodiments, the core layers 204a are completely removed while the intermix layers 205 are partially removed, thus the spacing T7 is less than (T5+2*T4). The core layers 204a and the removed intermix layers 205 can be collectively referred to as non-channel layers. In some embodiments, spacings of each openings 214 are substantially the same at different locations on an X-Y plane. For example, spacing of an opening 214 close to an edge (e.g., a portion directly under the gate spacer 212) is substantially the same (e.g., less than 5% difference) as spacing of the opening 214 at center (e.g., a portion directly under dummy gate stack 210).

In some embodiments, the spacing T7 is about 2 nm to about 14 nm. In some embodiments, each channel layer 206a has nanometer-sized dimensions and can be referred to as a “nanowire,” which generally refers to a channel layer suspended in a manner that will allow a metal gate to physically contact at least two sides of the channel layer, and in GAA transistors, will allow the metal gate to physically contact at least four sides of the channel layer (i.e., surround the channel layer). In such embodiments, a vertical stack of suspended channel layers can be referred to as a nanostructure, and the process depicted in FIGS. 5A and 5B can be referred to as a channel nanowire release process. In some embodiments, after removing the core layers 204a and the intermix layers 205, an etching process is performed to modify a profile of the channel layers 206a to achieve desired dimensions and/or desired shapes (e.g., cylindrical-shaped (e.g., nanowire), rectangular-shaped (e.g., nanobar), sheet-shaped (e.g., nanosheet), etc.). The present disclosure further contemplates embodiments where the channel layers 206a (nanowires) have sub-nanometer dimensions depending on design requirements of semiconductor structure 200.

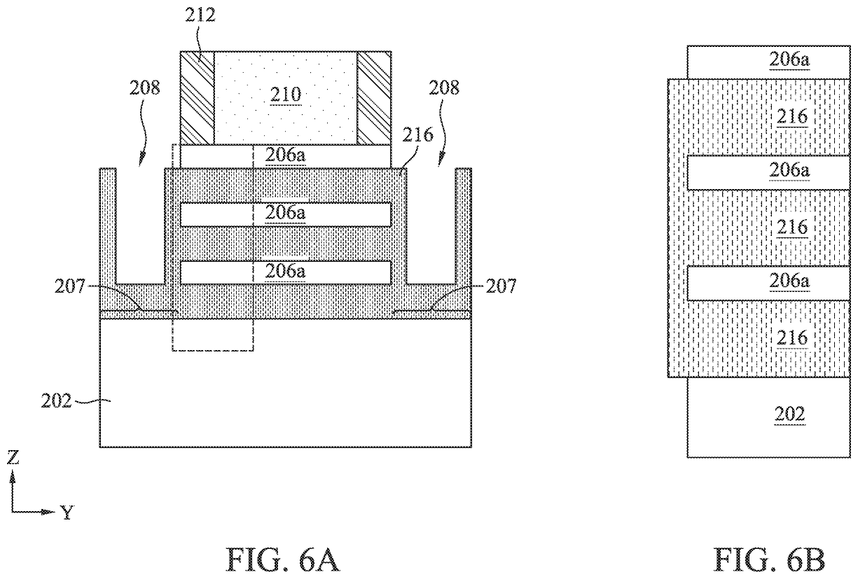

Referring to block 108 in FIG. 1 and FIG. 6A, a dielectric material 216 is deposited into the opening 214 and conformally over the source/drain regions 207. FIG. 6B is an enlarged view of a portion (in the dotted rectangle) of the semiconductor structure 200 in FIG. 6A. The depositing the dielectric material can include any suitable methods, such as atomic layer deposition (ALD), plasma enhanced atomic layer deposition (PEALD), physical vapor deposition (PVD), or combinations thereof. In some embodiments, the depositing the dielectric material include an atomic layer deposition (ALD) process. The conformally depositing the dielectric material 216 can form a layer of the dielectric material 216 of a thickness of about 2 nm to about 14 nm. In some embodiments, the thickness is about 2 nm to about 7 nm. In some embodiments, the thickness is about 2 nm to about 5 nm.

The dielectric material 216 can include any suitable materials that have an etching selectively different from the channel layers 206a. In some embodiments, the dielectric material 216 include an oxide material. The dielectric material 216 can include at least one of silicon oxide (SiO₂, SiO), silicon oxynitride (SiON), aluminum oxide (Al₂O₃), silicon nitride, SiOC, SiOCN, and a combination thereof. In some embodiments, the dielectric material 216 includes a composition different from the semiconductor layers 204. In some embodiments, the dielectric material 216 includes less than 0.001% (atomic percentage) of germanium (Ge) or is free of Ge. In some embodiments, the dielectric material 216 is free of SiGe. If Ge level in the dielectric material 216 is too high (e.g., greater than 1% atomic percentage), following processes may be impacted by Ge residue, which will be described in following descriptions.

In some embodiments, unlike the semiconductor layers 204 and 206, the channel layers 206a and the adjacent dielectric material 216 have clear boarders that are free of intermix sessions, which may include a mixture of materials of the channel layers 206a and the dielectric material 216. The channel layers 206a remain substantially unchanged (e.g., less than 5% changes) during the following processes, which will be described hereinbelow.

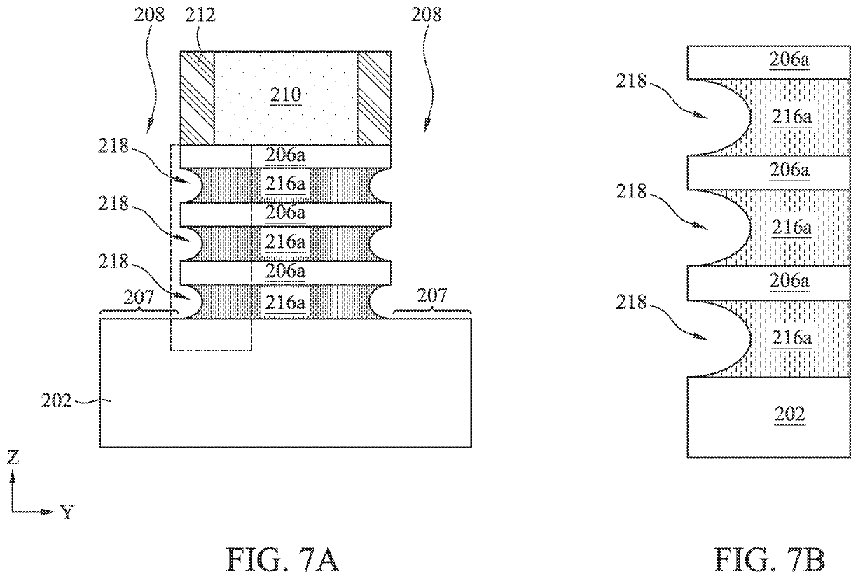

Referring to block 110 in FIG. 1 and FIG. 7A, the dielectric material 216 in the source/drain regions 207 is removed, and portions of the dielectric material 216 between the adjacent channel layers 206a (or the semiconductor substrate 202, where applicable) are recessed through exposed sidewall surfaces in the source/drain regions 207 via a selective etching process to form undercuts 218 and dielectric layers 216a (or dielectric interposers 216a). FIG. 7B is an enlarged view of a portion (in the dotted rectangle) of the semiconductor structure 200 in FIG. 7A.

The selective etching process may be any suitable processes, such as a wet etching or a dry etching process. The extent to which the dielectric material 216 are recessed (or the size of the portion removed) is determined by the processing conditions such as the duration the dielectric material 216 is exposed to an etching chemical. In the depicted embodiments, the duration is controlled such that the dielectric material 216 in the source/drain regions 207 is completely removed, and side portions of the dielectric material 216 between adjacent channel layers 206a (or the semiconductor substrate 202, where applicable) are removed, while center portions (e.g., the dielectric layer 216a) of the dielectric material 216 between the adjacent channel layers 206a (or the semiconductor substrate 202, where applicable) remain substantially unchanged. As illustrated in FIG. 7B, the selective etching process creates the undercuts 218, which extend the source/drain recesses 208 into areas beneath the channel layers 206a and the gate spacers 212.

In some embodiments, the undercuts 218 have a convex shape as depicted in FIG. 7B. In some embodiments, the dielectric layers 216a include tip portions extending towards sidewalls of the channel layers 206a (or the semiconductor substrate 202, where applicable). In some embodiments, the tip portions extend to directly contact an entirety of a top or a bottom surface of a channel layer 206a (or the semiconductor substrate 202, where applicable). In such embodiments, the dielectric layers 216a have a sidewall coplanar with a sidewall of the channel layers 206a.

Meanwhile, the channel layers 206a are only slightly affected during the selective etching process. For example, prior to the selective etching process, side portions of the channel layers 206a each has a thickness T3 or T6 (see FIG. 5B). After the selective etching process, thicknesses of the side portions of the channel layers 206a may have about 1% to 5% changes from T3 or T6. The etch selectivity between the channel layers 206a and the dielectric material 216 is made possible by the different material compositions between these layers. For example, the dielectric material 216 may be etched away at a substantially faster rate (e.g. more than about 5 times faster or about 10 times faster) than the channel layers 206a. Because spacings of each openings 214 as in FIGS. 5A-5B are substantially the same at different locations on an X-Y plane, and the channel layers 206a (or the semiconductor substrate 202, where applicable) remain substantially unchanged (e.g., less than 5% changes), spacing of each undercuts 218 along Z-direction is substantially the same as a thickness of each of the dielectric layers 216a (e.g., less than 5% difference), which is about the same as T7.

As discussed above, the selective etching process may be a wet etching process. The etching technique and etchant(s) may be selected to etch the dielectric material 216 without significant etching of the surrounding structures, such as the channel layers 206a. In an embodiment, the channel layers 206a include Si and the dielectric material 216 include an oxide material (e.g., silicon oxide). In an embodiment, a hydrofluoric acid (HF) solution, such as a dilute hydrofluoric acid (DHF), may be used to selectively etch away the dielectric material 216. For example, the dielectric material 216 may be etched away at a substantially faster rate than the channel layers 206a (e.g., with a selectivity greater than 10). As a result, desired portions of the dielectric material 216 (e.g. the side portions of the dielectric material 216 between the adjacent channel layers 206a (or the semiconductor substrate 202, where applicable)) are removed, while the channel layers 206a remain substantially unchanged. The etching duration is adjusted such that the size of the removed portions of the dielectric material 216 are controlled. The optimal condition may be reached by additionally adjusting the etching temperature, dopant concentration, as well as other experimental parameters.

In some embodiments, the selective etching process may include a dry, plasma-free etching process performed using a suitable etch system, such as CERTAS® Gas Chemical Etch System, available from Tokyo Electron Limited, Tokyo, Japan. In some examples, the selective etching process may include etching using a standard clean 1 (SC-1) solution, a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch.

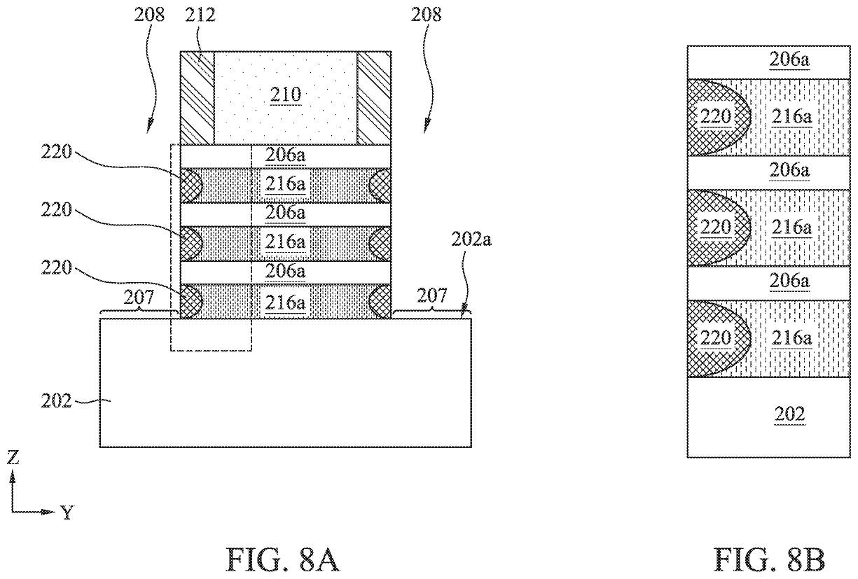

Referring to block 112 of FIG. 1A and FIG. 8A, a second dielectric material is deposited into the undercuts 218. Deposition of the second dielectric material forms a spacer layer over the dummy gate stack 210, the gate spacers 212, and over features defining the source/drain recesses 208 (e.g., the channel layers 206a, the dielectric layers 216a, and the semiconductor substrate 202), and includes methods such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the source/drain recesses 208. The deposition process is configured to ensure that the spacer layer fills the undercuts 218. An etching process is then performed that selectively etches the spacer layer to form inner spacers 220 as depicted in FIGS. 8A-8B with minimal (to no) etching of the channel layers 206a, the dummy gate stack 210, and the gate spacers 212. In some embodiments, the spacer layer is removed from sidewalls of the gate spacers 212, sidewalls of the channel layers 206a, the dummy gate stack 210, and the semiconductor substrate 202. The spacer layer (and thus inner spacers 220) includes a material that is different than a material of the channel layers 206a and a material of the gate spacers 212 to achieve desired etching selectivity during the etching process. In some embodiments, the spacer layer includes a material that is different than a material of the dielectric layers 216a. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material, such as those described herein. In some embodiments, dopants (for example, p-type dopants, n-type dopants, or combinations thereof) are introduced into the dielectric material, such that the spacer layer includes a doped dielectric material.

FIG. 8B is an enlarged view of a portion (in the dotted rectangle) of the semiconductor structure 200 in FIG. 8A. In embodiments, the inner spacers 220 fill the undercuts 218 and thus have a convex shape as depicted in FIG. 8B. In such embodiments, the dielectric layers 216a include tip portions between the inner spacers 220 and the channel layers 206a (or semiconductor substrate 202, where applicable). In some embodiments, the tip portions extend towards a sidewall of the ML but are not exposed to the source/drain recesses 208. In such embodiments, the inner spacers 220 separate the dielectric layers 216a from the source/drain recesses 208. In some other embodiments, although not depicted, the tip portions extend to directly contact an entirety of a top and/or a bottom surface of the channel layers 206a (or the semiconductor substrate 202, where applicable). In such embodiments, the dielectric layers 216a are exposed to the source/drain recesses 208 and separate the adjacent inner spacer 220 from the adjacent channel layers 206a (or the semiconductor substrate 202, where applicable). The dielectric layers 216a can have a sidewall coplanar with a sidewall of the channel layers 206a.

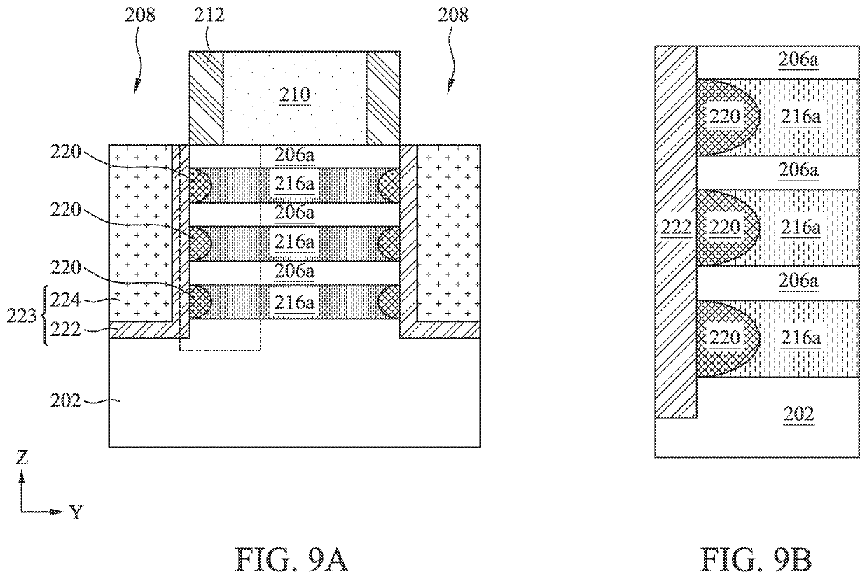

Referring to block 114 of FIG. 1A and FIGS. 9A-9B, the method 100 further includes forming epitaxial source/drain features 223 in the source/drain recesses 208. FIG. 9B is an enlarged view of a portion (in the dotted rectangle) of the semiconductor structure 200 in FIG. 9A. In some embodiments, one source/drain feature 223 is a source electrode, and the other source/drain feature 223 is a drain electrode. The channel layers 206a that extend from one source/drain feature 223 to the other source/drain feature 223 may form channels of the semiconductor structure 200. Multiple processes including etching and growth processes may be employed to grow the epitaxial source/drain features 223. Each of the epitaxial source/drain features 223 can include multiple layers, such as a first source/drain layer 222 and a second source/drain layer 224. In the depicted embodiment, the epitaxial source/drain features 223 have top surfaces that are substantially aligned with a top surface of the topmost channel layer 206a. However, in other embodiments, the epitaxial source/drain features 223 may alternatively have top surfaces that extend higher than the top surface of the topmost channel layer 206a (e.g. in the Z-direction). In the depicted embodiment, the epitaxial source/drain features 223 occupy a lower portion of the source/drain recesses 208 (e.g. the portion defined by the inner spacers 220 and the channel layers 206a), leaving an upper portion of the source/drain recesses 208 (e.g. the portion defined by the gate spacers 212) open. In some embodiments, the epitaxial source/drain features 223 may merge together, for example, along the X-direction, to provide a larger lateral width than an individual epitaxial feature.

The epitaxial source/drain features 223 may include any suitable semiconductor materials. For example, the epitaxial source/drain features 223 in an n-type GAA device may include Si, SiC, SiP, SiAs, SiPC, or combinations thereof; while the epitaxial source/drain features 223 in a p-type GAA device may include Si, SiGe, Ge, SiGeC, or combinations thereof. The epitaxial source/drain features 223 may be doped in-situ or ex-situ. For example, the epitaxially grown Si source/drain features may be doped with carbon to form silicon:carbon (Si:C) source/drain features, phosphorous to form silicon:phosphor (Si:P) source/drain features, or both carbon and phosphorous to form silicon carbon phosphor (SiCP) source/drain features; and the epitaxially grown SiGe source/drain features may be doped with boron. One or more annealing processes may be performed to activate the dopants in the epitaxial source/drain features 223. The annealing processes may include rapid thermal annealing (RTA) and/or laser annealing processes.

The epitaxial source/drain features 223 may directly interface with sidewalls of the inner spacers 220 and the channel layers 206a. During the epitaxial growth, semiconductor materials grow from the exposed top surface 202a of the semiconductor substrate 202 (e.g., the exposed top surface of doped region) as well as from the exposed side surfaces of the channel layers 206a. It is noted that semiconductor materials do not grow from the surfaces of the inner spacers 220 and the gate spacers 212 during the epitaxial growth process.

Because the semiconductor layers 204 and the intermix layers 205 have been removed referring to block 106 in FIG. 1, SiGe in the ML when forming the epitaxial source/drain features 223 is negligible (e.g., less than 0.0001% of the total SiGe in the semiconductor layers 204 at block 102), doping diffusion to undesired regions is reduced, and built-in stress (e.g., tensile stress and compressive stress) during processes is reduced.

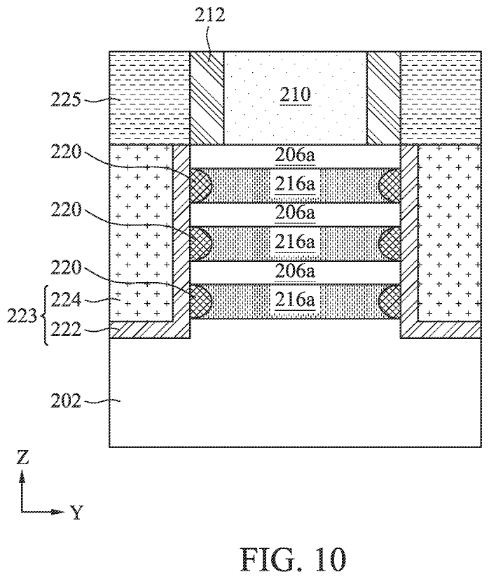

Referring to block 116 of FIG. 1A and FIG. 10, an interlayer dielectric (ILD) layer 225 is formed over the epitaxial source/drain features 223 in the remaining spaces of the source/drain recesses 208, as well as vertically over the isolation features 201. The ILD layer 225 may also be formed in between the adjacent dummy gate stacks 210 along the Y-direction, and in between the source/drain features 223 along the X-direction. The ILD layer 225 may include a dielectric material, such as a high-k material, a low-k material, or an extreme low-k material. For example, the ILD layer 225 may include SiO₂, SiOC, SiON, or combinations thereof. The ILD layer 225 may include a single layer or multiple layers, and may be formed by a suitable technique, such as CVD, ALD, and/or spin-on techniques. In some embodiments, a contact etch-stop layer (CESL) is disposed between the ILD layer 225 and the isolation features 201, the epitaxial source/drain features 223 and the gate spacers 212. The CESL includes a material different than the ILD layer 225, such as a dielectric material that is different than the dielectric material of the ILD layer 225 to achieve the etch selectivity. For example, where the ILD layer 225 includes a low-k dielectric material, the CESL includes silicon and nitrogen, such as silicon nitride or silicon oxynitride. Subsequent to the deposition of the ILD layer 225 and/or the CESL, a CMP process and/or other planarization process can be performed to remove excessive portions of the ILD layer 225, thereby planarizing a top surface of the ILD layer 225, until reaching (exposing) a top portion (or top surface) of the dummy gate stack 210. Among other functions, the ILD layer 225 provides electrical isolation between the various components of the semiconductor structure 200.

The ILD layer 225 may be a portion of a multilayer interconnect (MLI) feature disposed over the semiconductor substrate 202. The MLI feature electrically couples various devices (for example, a GAA transistor of the semiconductor structure 200, transistors, resistors, capacitors, and/or inductors) and/or components (for example, gate structures and/or epitaxial source/drain features of GAA transistors), such that the various devices and/or components can operate as specified by design requirements of the semiconductor structure 200. The MLI feature includes a combination of dielectric layers and electrically conductive layers (e.g., metal layers) configured to form various interconnect structures. The conductive layers are configured to form vertical interconnect features, such as device-level contacts and/or vias, and/or horizontal interconnect features, such as conductive lines. Vertical interconnect features typically connect horizontal interconnect features in different layers (or different planes) of the MLI feature. During operation, the interconnect features are configured to route signals between the devices and/or the components of the semiconductor structure 200 and/or distribute signals (for example, clock signals, voltage signals, and/or ground signals) to the devices and/or the components of the semiconductor structure 200.

Referring to block 118 of FIG. 1B and FIGS. 11A-11C, the dummy gate stack 210 is selectively removed through any suitable lithography and etching processes. In some embodiments, the lithography process includes forming a photoresist layer (resist), exposing the resist to a pattern, performing a post-exposure bake process, and developing the resist to form a masking element, which exposes a region including the dummy gate stack 210. Then, the dummy gate stack 210 is selectively etched through the masking element. In some other embodiments, the gate spacers 212 may be used as the masking element or a part thereof. For example, the dummy gate stack 210 may include polysilicon, the gate spacers 212 and the inner spacers 220 may include dielectric materials, and the channel layers 206a include a semiconductor material. Therefore, an etch selectivity may be achieved by selecting appropriate etching chemicals, such that the dummy gate stack 210 may be removed without substantially affecting the features of the semiconductor structure 200. The removal of the dummy gate stack 210 creates gate trench 228. The gate trench 228 exposes the top surfaces and the side surfaces of the stack of the channel layers 206a and the dielectric layers 216a. In other words, the channel layers 206a and the dielectric layers 216a are exposed at least on two side surfaces in the gate trench 228. Additionally, the gate trench 228 also exposes the top surfaces of the isolation features 201.

Referring to block 120 of FIG. 1B and FIGS. 11A-11C, the dielectric layers 216a are also selectively removed through the gate trench 228, for example using wet or dry etching process. The etching chemical is selected such that the dielectric layers 216a have a sufficiently different etching rate as compared to the channel layers 206a, the inner spacers 220, and the gate spacers 212. As a result, the channel layers 206a, the inner spacers 220, and the gate spacers 212 remain substantially unchanged. This selective etching process may include one or more etching steps.

As illustrated in FIGS. 11A-11C, in the present embodiment, the removal of the dielectric layers 216a forms suspended channel layers 206a and second openings 226 in between the vertically adjacent layers (e.g. in the Z-direction), thereby exposing the top and bottom surfaces of the channel layers 206a. Each of the channel layers 206a are now exposed circumferentially in the X-Z plane. In addition, the portion of the doped regions of the semiconductor substrate 202 beneath the channel layers 206a are also exposed in the second openings 226.

In the examples depicted in FIGS. 11A-11C, the gate trench 228 and the second openings 226 vertically adjacent to the gate trench 228 (e.g. in the Z-direction) collectively form an opening having a vertical profile. In other words, the opening collectively formed by the gate trench 228 and its corresponding second openings 226 have vertical sidewalls. In some embodiments, such openings having the vertical sidewalls may be formed by a plurality of etch processes. For example, the etch chemistry of the etch process used to remove the dummy gate stack 210 and thereby form the gate trench 228 may include hydrogen bromide (HBr) combined with chlorine (Cl₂), tetrafluoromethane (CF₄), oxygen, or a combination thereof. Furthermore, the etch process used to selectively remove the dielectric layers 216a and thereby form the second openings 226 may have an initial etch chemistry including hydrogen bromide (HBr) combined with chlorine (Cl₂), oxygen, or a combination thereof. This initial etch chemistry is followed by a subsequent etch chemistry including hydrogen bromide (HBr) combined with tetrafluoromethane (CF₄), oxygen, or a combination thereof that induces the vertical profile of the opening collectively formed by the gate trench 228 and its corresponding second openings 226.

FIG. 11B is an enlarged view of a portion (in the dotted rectangle) of the semiconductor structure 200 in FIG. 11A. In some embodiments, the removal process only removes some but not all of the dielectric layers 216a. A portion of the dielectric layers 216a may remain between the inner spacers 220 and the channel layers 206a (or the semiconductor substrate 202, where applicable). Such remaining portion can be referred to as “remaining dielectric layers 216b.”

In some embodiments, the remaining dielectric layers 216b are free of SiGe. In conventional processes, non-channel layers including SiGe are commonly used. After forming epitaxial source/drain features, most of non-channel layers are removed while SiGe residue can remain between adjacent channel layers, causing undesired capacitance between the SiGe residue and adjacent conductive features. In the present disclosure, the semiconductor layers 204 and the intermix layers 205 have been removed referring to block 106 in FIG. 1, thus SiGe in the ML is negligible (e.g., less than 0.0001% of the total SiGe in the semiconductor layers 204 at block 102), thus capacitance between SiGe and other conductive features (e.g., the epitaxial source/drain features 223) is reduced or negligible.

In some embodiments, an etching selectivity of the dielectric layers 216a to the channel layers 206a can be higher than an etching selectivity of the semiconductor layers 204 to the channel layers 206a in conventional processes. In some embodiments, in the removing of the dielectric layers 216a, an etching selectivity of the dielectric layers 216a to the channel layers 206a is greater than 10. If the etching selectivity of the dielectric layers 216a to the channel layers 206a is too small, the channel layers 206a may be etched, thus thicknesses and/or widths of the channel layers 206a may be reduced, which may impact performance of the semiconductor structure 200 (e.g., more SCEs, higher capacitance).

FIG. 11C is a sectional view of the semiconductor structure 200 in FIG. 11A and along the line B-B′ in FIG. 2. In some embodiments, the channel layers 206a has no or little width loss during the removal of the dielectric layers 216a. This can result from the etching selectivity of the dielectric layers 216a to the channel layers 206a, and/or that the channel layers 206a and the adjacent dielectric material 216 have clear boarders that are free of intermix session, as describe above. In some embodiments, the channel layers 206a have a width along the X-direction that is equal to or less than a width of a bottom portion of the fin 203 (e.g., a portion of fin 203 contacting the semiconductor substrate 202) along the X-direction by less than 2%. In other words, width loss of the channel layers 206a in the process is negligible, which improves device performance and reduces capacitance.

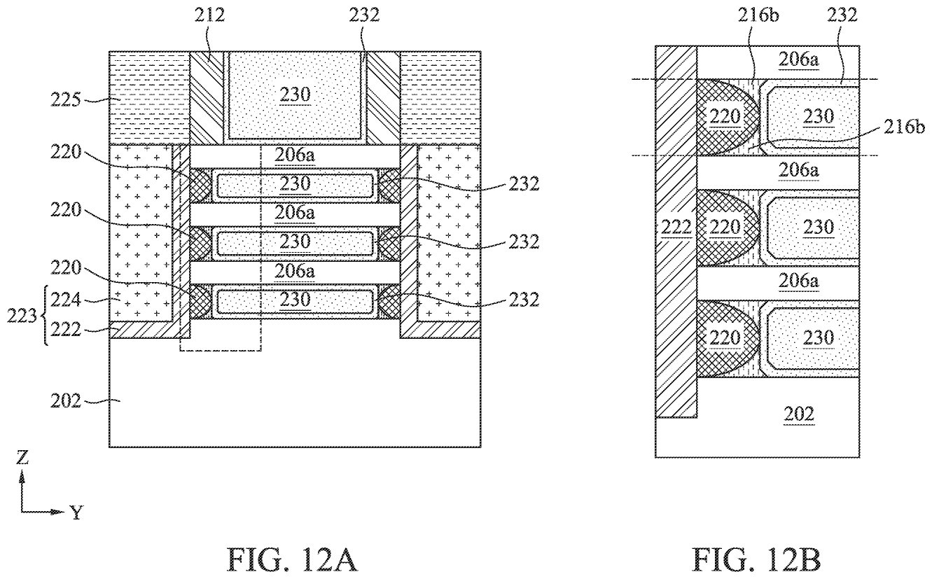

Referring to block 122 of FIG. 1B and FIGS. 12A-12B, a metal gate stack is formed. The metal gate stack includes a gate dielectric layer 232 and a gate electrode 230 disposed over the gate dielectric layer 232. For example, the metal gate stack may include a polysilicon gate electrode over a SiON gate dielectric layer. As another example, the metal gate stack may include a metal gate electrode over a high-k dielectric layer. In some instances, a refractory metal layer may interpose between the metal gate electrode (such as an aluminum gate electrode) and the high-k dielectric layer. As yet another example, the metal gate stack may include silicide. The gate dielectric layer 232 is formed between the gate electrode 230 and the channels formed by the channel layers 206a.

In some embodiments, the gate dielectric layer 232 is formed conformally on the semiconductor structure 200. The gate dielectric layer 232 at least partially fills the gate trenches 228. In some embodiments, dielectric interfacial layers may be formed over the channel layers 206a prior to forming the gate dielectric layer 232. Such dielectric interfacial layers improve the adhesion between the channel layers 206a and the gate dielectric layer 232. In the examples depicted in this disclosure, such dielectric interfacial layers are omitted. Instead, in the embodiments shown, the gate dielectric layer 232 is formed around the exposed surfaces of each of the channel layers 206a, such that it wraps around the channel layers 206a in 360 degrees. Additionally, the gate dielectric layer 232 also directly contacts vertical sidewalls of the inner spacers 220, sidewalls of the remaining dielectric layers 216b, and vertical sidewalls of the gate spacers 212. The gate dielectric layer 232 may include a dielectric material having a dielectric constant greater than a dielectric constant of SiO₂, which is approximately 3.9. For example, the gate dielectric layer 232 may include hafnium oxide (HfO₂), which has a dielectric constant in a range from about 18 to about 40. As various other examples, the gate dielectric layer 232 may include ZrO₂, Y₂O₃, La₂O₅, Gd₂O₅, TiO₂, Ta₂O₅, HfErO, HfLaO, HfYO, HfGdO, HfAlO, HfZrO, HfTiO, HfTaO, SrTiO, or combinations thereof. The formation of the gate dielectric layer 232 may be by any suitable processes, such as CVD, PVD, ALD, or combinations thereof.

After forming the gate dielectric layer 232, the gate electrode 230 is formed over the gate dielectric layer 232 to fill the remaining spaces of the gate trenches 228. The gate electrode 230 may include any suitable materials, such as titanium nitride (TiN), tantalum nitride (TaN), titanium aluminide (TiAl), titanium aluminum nitride (TiAlN), tantalum aluminide (TaAl), tantalum aluminum nitride (TaAlN), tantalum aluminum carbide (TaAlC), tantalum carbonitride (TaCN), aluminum (Al), tungsten (W), copper (Cu), cobalt (Co), nickel (Ni), platinum (Pt), or combinations thereof. In some embodiments, a CMP is performed to expose a top surface of the ILD layer 225. The gate dielectric layer 232 and the gate electrode 230 collectively form the metal gate stack, which engages multiple layers within the channel layers 206a (e.g. multiple nanochannels).

FIG. 12B is an enlarged view of a portion (in the dotted rectangle) of the semiconductor structure 200 in FIG. 12A. As previously described in this disclosure, thicknesses along the Z-direction of each channel layers 206a are substantially the same at different locations on an X-Y plane, and the channel layers 206a are substantially unchanged through the process, thus after forming the metal gate stack, thicknesses along the Z-direction of each channel layers 206a remain substantially the same (e.g., less than 5% difference) at different locations on an X-Y plane. If the thicknesses along the Z-direction of each channel layers 206a are not substantially the same (e.g., less than 5% difference) at different locations on an X-Y plane, for example, a thickness on edges (e.g., closer to epitaxial source/drain features) is greater than 10% of a thickness in center (e.g., directly under the metal gate stack above the ML), undesired capacitance may increase. While in conventional processes, non-channel layers including SiGe are commonly removed after forming epitaxial source/drain features and before forming the metal gate stack, and the removing of the non-channel layers include multiple etching steps for removal of intermix layers, which cause width reduction of channel layers (e.g., width along x direction) and thicker channel layers on edges (e.g., closer to epitaxial source/drain features) than in center (e.g., directly under the metal gate stack above the ML), thus impact device performance (e.g., increased SCEs) and increase undesired capacitance. In addition, SiGe in the ML of the present disclosure is negligible (e.g., less than 0.0001% of the total SiGe in the semiconductor layers 204 at block 102), thus forming of oxidized Ge during the processes is negligible, which reduces interface trap effect.

In some embodiments, as depicted in FIG. 12B, in each of the second openings 226 between the two adjacent channel layers 206a (or the semiconductor substrate 202, where applicable) (referred to as “top channel layer 206a” and “bottom channel layer 206a”), there are at least one of the remaining dielectric layers 216b (referred as “top remaining dielectric layer 216b” or “bottom remaining dielectric layer 216b”) in direct contact with the top channel layer 206a or the bottom channel layer 206a. The top and/or bottom remaining dielectric layer 216b can have a triangle-like shape in the cross sectional view as in FIG. 12B. In some embodiments, sidewalls of the top and/or bottom remaining dielectric layer 216b interface with the top and/or bottom channel layer 206a, the adjacent inner spacer 220, and the adjacent gate dielectric layer 232, respectively. In some other embodiments, although not depicted, besides interfacing with these, the top and/or bottom remaining dielectric layer 216b extend to contact with the adjacent epitaxial source/drain feature 223. In such embodiments, the adjacent inner spacer 220 is separated from the top and/or bottom channel layer 206a by the top and/or bottom remaining dielectric layer 216b.

In some embodiments, the top and/or bottom remaining dielectric layer 216b extend between one of the inner spacers 220 (first inner spacer 220) and the gate dielectric layer 232. In some embodiments, the top remaining dielectric layer 216b and the bottom remaining dielectric layer 216b are separated by the first inner spacer 220 and the gate dielectric layer 232 of the metal gate stack. In some other embodiments, the top remaining dielectric layer 216b extends and merges with the bottom remaining dielectric layer 216b. In some embodiments, the top remaining dielectric layer 216b extends to the top channel layer 206a. A top surface of the top remaining dielectric layer 216b and a top surface of the gate dielectric layer 232 can be coplanar, and can be in direct contact with a bottom surface of the top channel layer 206a. Similarly, the bottom remaining dielectric layer 216b extends to the bottom channel layer 206a. A bottom surface of the bottom remaining dielectric layer 216b and a bottom surface of the gate dielectric layers 232 can be coplanar, and can be in direct contact with a top surface of the bottom channel layer 206a.

After forming the gate dielectric layer 232 and the gate electrode 230, a planarization process is performed to remove excess gate materials from the semiconductor structure 200. For example, a CMP process is performed until a top surface of the ILD layer 225 is reached (exposed), such that a top surface of the metal gate stack is substantially planar with the top surface of the ILD layer 225 after the CMP process. Accordingly, the semiconductor structure 200 can include a GAA transistor having a metal gate stack wrapping respective channel layers 206a, such that the metal gate stack is disposed between respective epitaxial source/drain features 223.

Fabrication can proceed to continue fabrication of the semiconductor structure 200. For example, various contacts can be formed to facilitate operation of the GAA transistor. For example, one or more ILD layers, similar to the ILD layer 225, and/or CESL layers can be formed over the semiconductor substrate 202 (in particular, over the ILD layer 225 and the metal gate stack). Contacts can then be formed in the ILD layer 225 and/or ILD layers disposed over the ILD layer 225. For example, a contact is electrically and/or physically coupled with the metal gate stack and another contact is electrically and/or physically coupled to source/drain regions of the GAA transistor (particularly, the epitaxial source/drain features 223). Contacts include a conductive material, such as metal. Metals include aluminum, aluminum alloy (such as aluminum/silicon/copper alloy), copper, copper alloy, titanium, titanium nitride, tantalum, tantalum nitride, tungsten, polysilicon, metal silicide, other suitable metals, or combinations thereof. The metal silicide may include nickel silicide, cobalt silicide, tungsten silicide, tantalum silicide, titanium silicide, platinum silicide, erbium silicide, palladium silicide, or combinations thereof. In some implementations, the ILD layers disposed over the ILD layer 225 and the contacts (for example, extending through the ILD layer 225 and/or the other ILD layers) are a portion of the MLI feature described above.

Other fabrication processes may be applied to the semiconductor structure 200 and may implemented before, during, or after the processes described above, such as various processing steps to form an interconnect structure over the GAA transistors from the frontside of the semiconductor substrate 202 to electrically connects various circuit components. The interconnect structure includes metal lines distributed in multiple metal layers (such as 1^{st} metal layer, 2^{nd} metal layer, 3^{rd} metal layer, and etc. from the bottom up to the top metal layer) to provide horizontal routing and contact features (between the substrate and the first metal layer, and via features (between the metal layers) to provide vertical routing. The semiconductor structure 200 also includes other components, such as other conductive features (such as redistribution layer or RDL), passivation layer(s) to provide sealing effect, and/or bonding structures to provide an interface between the semiconductor structure 200 and a circuit board (such as a printed circuit board) to be formed on the interconnect structure.

Though not intended to be limiting, embodiments of the present disclosure offer benefits for semiconductor processing and semiconductor devices. For example, by removing the non-channel layers including the transition layers before forming the epitaxial source/drain features, SiGe residue becomes negligible before forming the epitaxial source/drain features, thus abnormal doping diffusion and built-in stress (e.g., tensile stress and compressive stress) during following processes are reduced. The early removal of the transition layers also reduces undesired capacitance and device degradation, avoids width loss of channel layers, thus improves performance of the device, reduces short-channel effects (SCEs), and can result in higher current drive and higher logic density.

In one example aspect, the present disclosure provides a method that includes: forming a structure having a dummy gate stack over a multi-layer stack (ML) disposed on a semiconductor substrate, the ML including alternating channel layers and non-channel layers; recessing the ML in source/drain (S/D) regions; removing the non-channel layers to form first openings between the channel layers; depositing a dielectric material in the first openings; recessing the dielectric material to form undercuts; forming inner spacers in the undercuts; forming epitaxial S/D features in the S/D regions; removing the dummy gate stack to form a gate trench; removing the dielectric material from the gate trench to form second openings between the channel layers; and forming a metal gate stack in the gate trench and the second openings.

Another one aspect of the present disclosure pertains to a method that includes: receiving a structure having a dummy gate stack over a multi-layer stack (ML) disposed on a semiconductor substrate, the ML including alternating channel layers and non-channel layers and source/drain (S/D) regions adjacent to the channel layers and non-channel layers; replacing the non-channel layers with a dielectric material; recessing the dielectric material to form undercuts; forming inner spacers in the undercuts; forming epitaxial S/D features in the S/D regions; and replacing the dummy gate stack and a portion of the dielectric material with a metal gate stack.

Yet another aspect of the present disclosure pertains to a semiconductor structure. The semiconductor structure includes a stack of semiconductor layers disposed over a substrate; a gate structure wrapping around each of the stack of semiconductor layers; an inner spacer interposed between the gate structure and a source/drain (S/D) feature and extending between two adjacent semiconductor layers of the stack of semiconductor layers; and a first dielectric layer disposed on a sidewall of the gate structure, contacting the inner spacer, and extending to a first semiconductor layer of the two adjacent semiconductor layers, wherein the inner spacer and the first dielectric layer include different compositions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a structure having a dummy gate stack over a multi-layer stack (ML) disposed on a semiconductor substrate, the ML including alternating channel layers and non-channel layers;
recessing the ML in source/drain (S/D) regions;
removing the non-channel layers to form first openings between the channel layers;
depositing a dielectric material in the first openings;
recessing the dielectric material to form undercuts;
forming inner spacers in the undercuts;
forming epitaxial S/D features in the S/D regions;
removing the dummy gate stack to form a gate trench;
removing the dielectric material from the gate trench to form second openings between the channel layers; and
forming a metal gate stack in the gate trench and the second openings.

2. The method of claim 1, wherein
the S/D regions include a first S/D region and a second S/D region;
the dummy gate stack is interposed between the first and second S/D regions; and
the depositing a dielectric material in the first openings includes depositing the dielectric material continuously extending from the first S/D region to the second S/D region.

3. The method of claim 1, prior to the removing the dummy gate stack, further comprising forming an interlayer dielectric (ILD) layer over the epitaxial S/D features, wherein the depositing the dielectric material includes performing an atomic layer deposition (ALD) process.

4. The method of claim 1, wherein
the dielectric material is silicon oxide; and
the recessing the dielectric material includes etching the dielectric material with hydrofluoric acid (HF).

5. The method of claim 1, wherein the ML further includes intermix layers having a mixture of materials of the channel layers and non-channel layers, and wherein removing the non-channel layers includes removing the intermix layers.

6. The method of claim 1, wherein forming the metal gate stack includes:
forming a high-k dielectric layer in the gate trench and the second openings; and
forming a metal gate electrode over the high-k dielectric layer to fill the gate trench and the second openings, the metal gate electrode wrapping around each of the channel layers.

7. The method of claim 1, wherein the inner spacers include a different composition from the dielectric material.

8. The method of claim 1, wherein the dielectric material includes at least one of silicon oxide, silicon oxynitride (SiON), aluminum oxide (Al₂O₃), silicon nitride, and a combination thereof.

9. The method of claim 1, wherein the channel layers include elemental silicon, and wherein the non-channel layers include silicon germanium (SiGe).

10. The method of claim 1, wherein the removing the dielectric material includes applying an etching process with an etchant having an etching selectivity of the dielectric material to the channel layers greater than 10.

11. The method of claim 1, wherein after removing the dielectric material, a first remaining portion of the dielectric material extends between a first inner spacer of the inner spacers and a gate dielectric layer of the metal gate stack in one of the second openings between two adjacent channel layers.

12. The method of claim 11, wherein a top surface of the first remaining portion of the dielectric material and a top surface of the gate dielectric layer of the metal gate stack are coplanar and are in direct contact with a bottom surface of a top channel layer of the two adjacent channel layers.

13. The method of claim 11, wherein a second remaining portion of the dielectric material extends between the first inner spacer of the inner spacers and the gate dielectric layer of the metal gate stack, and wherein the first and second remaining portions of the dielectric material are separated by the first inner spacer and the gate dielectric layer of the metal gate stack.

14. The method of claim 13, wherein the first remaining portion of the dielectric material extends to a first channel layer of the two adjacent channel layers, and wherein the second remaining portion of the dielectric material extends to a second channel layer of the two adjacent channel layers.

15. A method, comprising:
receiving a structure having a dummy gate stack over a multi-layer stack (ML) disposed on a semiconductor substrate, the ML including alternating channel layers and non-channel layers and source/drain (S/D) regions adjacent to the channel layers and non-channel layers;
replacing the non-channel layers with a dielectric material;
recessing the dielectric material to form undercuts;
forming inner spacers in the undercuts;
forming epitaxial S/D features in the S/D regions; and
replacing the dummy gate stack and a portion of the dielectric material with a metal gate stack.

16. The method of claim 15, prior to the replacing the dummy gate stack and the portion of the dielectric material, further comprising forming an interlayer dielectric (ILD) layer over the epitaxial S/D features.

17. The method of claim 15, wherein replacing the dummy gate stack and the portion of the dielectric material includes:
removing the dummy gate stack to form a gate trench;
removing the portion of the dielectric material to form openings between the channel layers; and
forming the metal gate stack in the gate trench and the openings.

18. The method of claim 17, wherein the removing the portion of the dielectric material includes applying an etching process with an etchant selectively removing the dielectric material without significantly etching the channel layers.

19. A semiconductor structure, comprising:
a stack of semiconductor layers disposed over a substrate;
a gate structure wrapping around each of the stack of semiconductor layers;
an inner spacer interposed between the gate structure and a source/drain (S/D) feature and extending between two adjacent semiconductor layers of the stack of semiconductor layers; and
a first dielectric layer disposed on a sidewall of the gate structure, contacting the inner spacer, and extending to a first semiconductor layer of the two adjacent semiconductor layers, wherein the inner spacer and the first dielectric layer include different compositions.

20. The semiconductor structure of claim 19, further comprising a second dielectric layer disposed on the sidewall of the gate structure, contacting the inner spacer, and extending to a second semiconductor layer of the two adjacent semiconductor layers, wherein the first and second dielectric layers include a same composition.
